(19) United States
(12) Patent Application Publication
(10) Pub. No.: US 2026/0177180 A1
(43) Pub. Date: Jun. 25, 2026

(54) COUPLING ASSEMBLY

(71) Applicant: COOLER MASTER CO., LTD., Taipei City (TW)

(72) Inventors: Hsiang-Chieh TSENG, Taipei City (TW); Yi-Ching LIN, Taipei City (TW)

(73) Assignee: COOLER MASTER CO., LTD., Taipei City (TW)

(21) Appl. No.: 19/416,041

(22) Filed: Dec. 11, 2025

Related U.S. Application Data
(60) Provisional application No. 63/738,167, filed on Dec. 23, 2024.

(51) Int. Cl. F16L 37/50

(52) U.S. Cl. CPC F16L 37/50

(57) ABSTRACT

A coupling assembly for a blind mate fluid coupling includes a housing unit with a through channel extending axially and a first recessed portion at a first end. A slide plate is disposed in the first recessed portion and movable in a first radial direction perpendicular to the axial direction, the slide plate having an opening. A slide base has a flat portion and a sleeve portion extending through the opening of the slide plate. The slide base is movable in a second radial direction perpendicular to both the axial direction and the first radial direction. The sleeve portion includes a tapered channel with a gradually narrowing diameter towards the flat portion. An inlet valve is at least partially disposed in the tapered channel and is movable in the axial direction and angularly pivotable within the tapered channel. This two-stage floating mechanism could accommodate radial, axial, and angular misalignment during blind mate coupling operations.

### RELATED APPLICATIONS

This US application claims priority under 35 U.S.C. § 119(e) to U.S. Provisional Patent Application No. 63/738,167, filed on December 23, 2024, which is incorporated herein by reference in its entirety.

### TECHNICAL FIELD

The present disclosure is related to the field of fluid coupling assemblies, in particular a floating quick fluid connector.

### BACKGROUND

In electronic applications, the fluid connectors are used to connect tubes or pipes to cold plates that require fluid flow for cooling or other similar purposes. Typically, barbed fittings are generally utilized to connect tubes to ports on cold plates. The barb is secured to the port, and the tube is pushed over the barb to create a secure and fluid-tight connection.

However, there are certain shortcomings with this design. The secured connection between the barb and the port prevents the tube from movement at all. As a result, the assembly is highly sensitive to misalignment during installation. Any minor alignment errors may impose strains on the tube and connection, perhaps resulting in damage or leaks over time. The tight connection makes it difficult to detach and reconnect tubes during maintenance or component replacements. Significant force is often required to remove the tube from the barb, which might damage the tubing or surrounding components, particularly in densely packed systems.

The aforementioned constraints are particularly evident in appliances that require frequent maintenance or where precise alignment is difficult to achieve. Because the connector or tube cannot withstand axial or angular movement, it may undergo mechanical stress, wear, and eventually break down.

### SUMMARY

Aspects of the disclosure provide a coupling assembly for a blind mate fluid coupling. The coupling assembly can include a housing unit having a first end and a second end, the housing unit includes a through channel extending in an axial direction from the first end to the second end, the housing unit having a first recessed portion at the first end, a slide plate disposed in the first recessed portion and movable in a first radial direction relative to the housing unit, the first radial direction being perpendicular to the axial direction, the slide plate includes an opening, a slide base having a flat portion and a sleeve portion, the sleeve portion extending through the opening of the slide plate, the slide base being movable in a second radial direction relative to the slide plate, the second radial direction being perpendicular to both the axial direction and the first radial direction, wherein the sleeve portion includes a tapered channel configured with a gradually narrowing diameter towards the flat portion, and an inlet valve at least partially disposed in the tapered channel of the slide base, the inlet valve being movable in the axial direction and angularly pivotable within the tapered channel.

In an embodiment, the opening of the slide plate has an oval shape with a first opening diameter along the second radial direction greater than a second opening diameter along the first radial direction, allowing the slide base to move in the second radial direction.

In an embodiment, the slide plate has a width equal to an opening width of the first recessed portion and a length shorter than an opening length of the first recessed portion, allowing the slide plate to move in the first radial direction.

In an embodiment, the coupling assembly can further include an outlet valve connected to a first end of the inlet valve, the outlet valve being in fluid communication with an inlet fluid channel of the inlet valve during operation, wherein the outlet valve includes a flange structure facing the inlet valve.

In an embodiment, the coupling assembly can further include a spring sleeved on the inlet valve, wherein one end of the spring is disposed in a concave portion of the flat portion of the slide base and the other end of the spring is disposed against a second end of the inlet valve, the spring being configured to provide axial movement in the axial direction and being retained between the slide base and the inlet valve. In an embodiment, the flat portion of the slide base includes the concave portion configured to restrict radial movement of the spring.

In an embodiment, the coupling assembly can further include a nut configured to secure on the sleeve portion of the slide base, the nut including a flange portion disposed in a groove of the housing unit, wherein a diameter of the flange portion is smaller than an opening size of the groove of the housing unit and greater than an opening size of a center portion of the housing unit. In some embodiments, the coupling assembly can further include at least one O-ring disposed between the nut and the housing unit.

In an embodiment, the coupling assembly can further include a guide structure connected to the inlet valve at the second end and configured to engage with a guide pin extending from a mating connector for blind mate coupling. In some embodiments, the guide structure is detachable from the inlet valve. In some embodiments, the guide structure is integrally formed with the inlet valve.

In an embodiment, the coupling assembly can further include at least one protrusion structure disposed on the slide base and a slot disposed on an outer surface of the inlet valve, wherein the at least one protrusion structure engages with the slot to prevent rotation around the axial direction.

In an embodiment, the tapered channel provides angular movement of 2° or less than 2° to the inlet valve. In an embodiment, the second end of the inlet valve includes a flange structure configured to retain the spring on the inlet valve. In an embodiment, the coupling assembly can further include a quick connect fitting connected to the second end of the inlet valve. In an embodiment, the slide base includes multiple protrusion structures disposed at angular positions around a circumference of the tapered channel.

Aspects of the disclosure provide a coupling assembly for a blind mate fluid coupling. The coupling assembly can include a housing unit, a slide plate disposed within the housing unit and configured to move in a first radial direction, the slide plate including a recessed portion and an opening, a slide base including a slide portion and a guide portion, the slide portion disposed in the recessed portion of the slide plate and configured to move in a second radial direction perpendicular to the first radial direction, wherein the guide portion is configured to engage with a guide pin of a mating connector, and a valve having a first end and a second end, the valve extending through the opening of the slide plate and the slide base, wherein the valve includes a fluid channel extending from the first end to the second end.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIGS. 1A-1B illustrate perspective views of a coupling assembly 100 according to aspects of the present disclosure.

FIG. 1C illustrates an exploded perspective view of the coupling assembly 100 as shown in FIGS. 1A.

FIG. 1D illustrates a cross-sectional view of the coupling assembly 100 as shown in FIGS. 1A.

FIG. 1E illustrates a front view of a housing unit 102 of coupling assembly 100 as shown in FIGS. 1A.

FIG. 1F illustrates a cross-sectional view of the housing unit 102 of coupling assembly 100 as shown in FIGS. 1A.

FIG. 2A illustrates a front view of the coupling assembly 100 in a first position along Y-direction demonstrating radial float capability.

FIG. 2B illustrates a cross-sectional view of the coupling assembly 100 in a first position along Y-direction demonstrating radial float capability.

FIG. 3A illustrates a front view of the coupling assembly 100 in a second position along Y-direction demonstrating radial float capability.

FIG. 3B illustrate a cross-sectional view of the coupling assembly 100 in a second position along Y-direction demonstrating radial float capability.

FIG. 4A illustrates a front view of the coupling assembly 100 in a first position along X-direction demonstrating radial float capability.

FIG. 4B illustrates a cross-sectional view of the coupling assembly 100 in a first position along X-direction demonstrating radial float capability.

FIG. 5A illustrates a front view of the coupling assembly 100 in a second position along X-direction demonstrating radial float capability.

FIG. 5B illustrates a cross-sectional view of the coupling assembly 100 in a second position along X-direction demonstrating radial float capability.

FIG. 6A illustrates a cross-sectional view of the coupling assembly 100 in a first axial position demonstrating axial float capability.

FIG. 6B illustrates a cross-sectional view of the coupling assembly 100 in a second axial position demonstrating axial float capability.

FIG. 7A illustrates a cross-sectional view of the coupling assembly 100 in a first angular position demonstrating angular float capability.

FIG. 7B illustrates a cross-sectional view of the coupling assembly 100 in a second angular position demonstrating angular float capability.

FIGS. 8A-8B illustrate enlarged cross-sectional views of the coupling assembly 100 demonstrating angular float capability.

FIG. 9A illustrates a perspective views of a rotation limiting mechanism of the coupling assembly 100.

FIG. 9B illustrates another perspective views of the rotation limiting mechanism of the coupling assembly 100.

FIGS. 10A-10B illustrate enlarged cross-sectional views of the coupling assembly 100.

FIG. 11 illustrates an exploded perspective view of a coupling assembly 100A according to aspects of the present disclosure.

FIG. 12 illustrates an exploded perspective view of a coupling assembly 100B according to aspects of the present disclosure.

FIG. 13 illustrates a perspective view of the inlet valve 112B of the coupling assembly 100B.

FIG. 14A illustrates a perspective view of a coupling assembly 100C according to aspects of the present disclosure.

FIG. 14B illustrates an exploded perspective view of the coupling assembly 100C shown in FIG. 14A.

FIG. 15A-15B illustrates the coupling assembly 100 in a detached position during operation.

FIG. 16A-16B illustrates the coupling assembly 100 in an attached position during operation.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

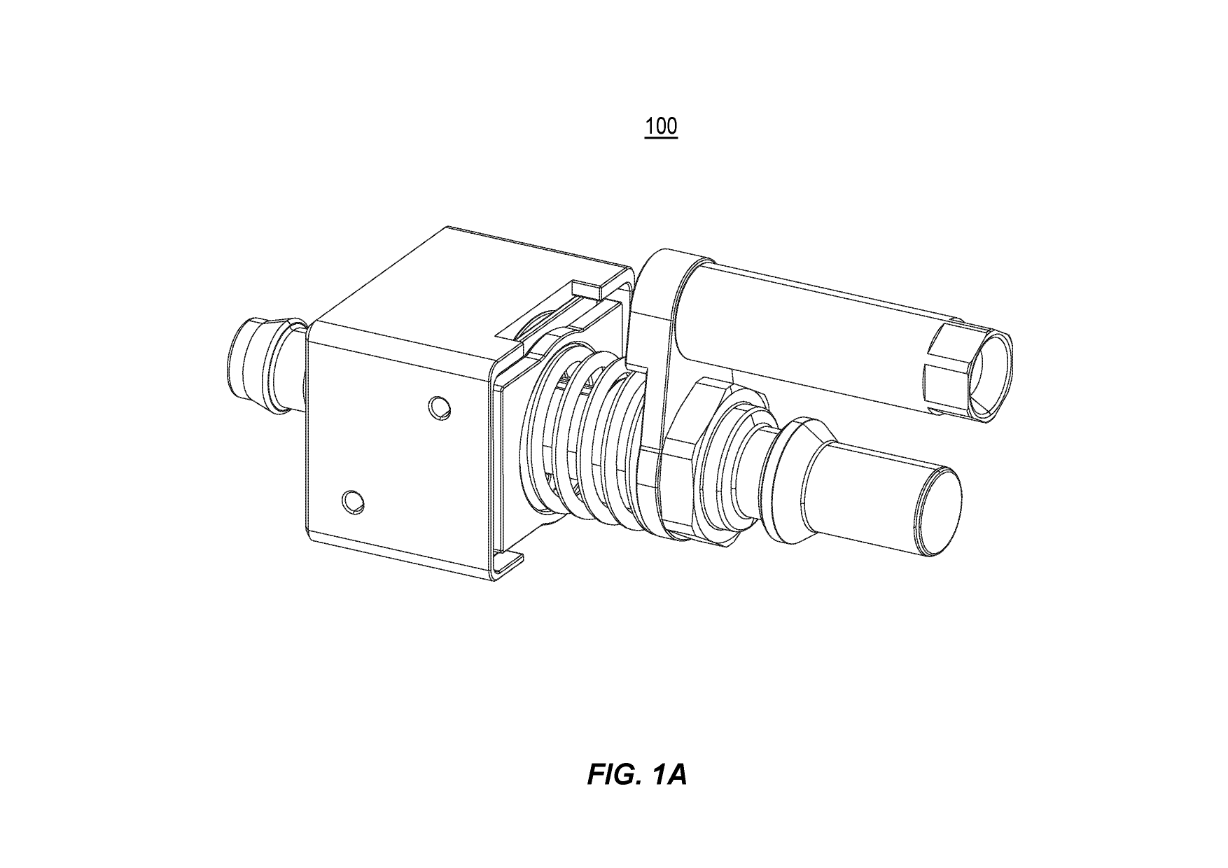

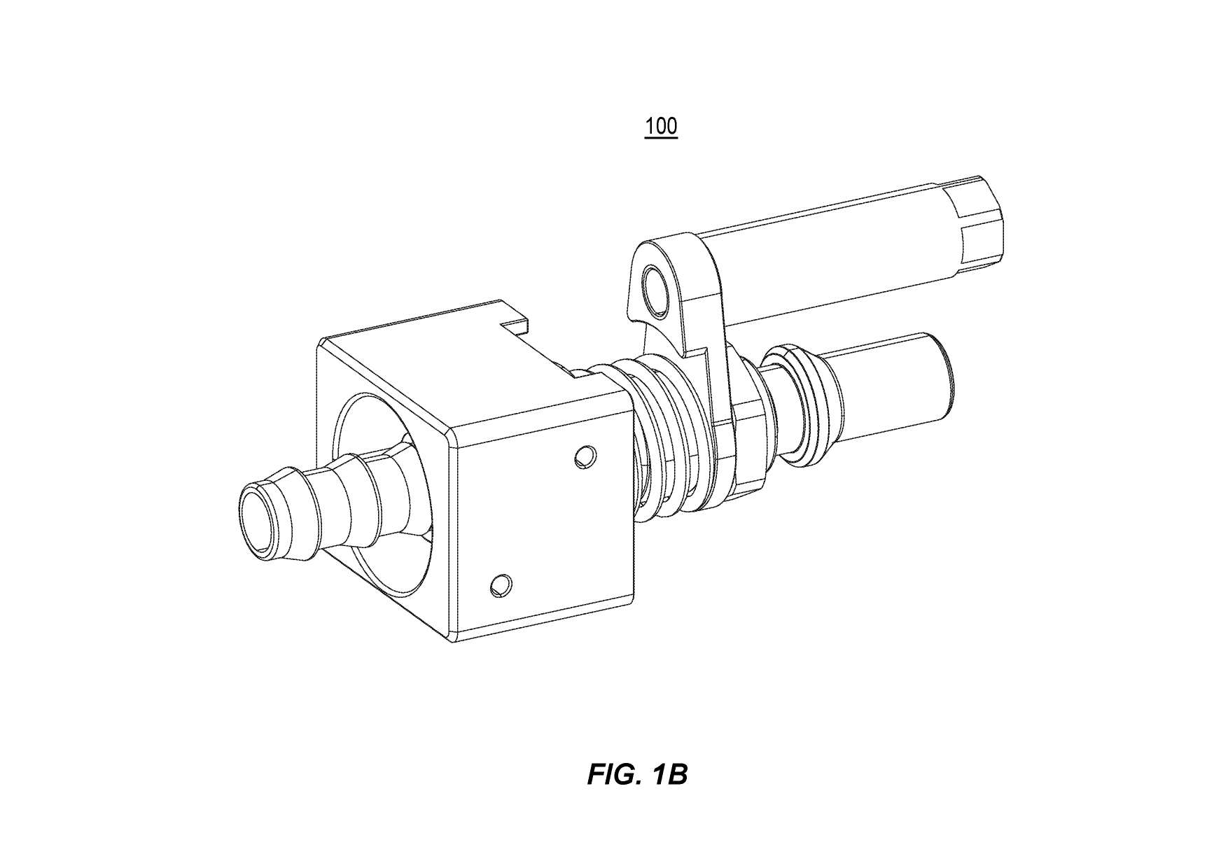

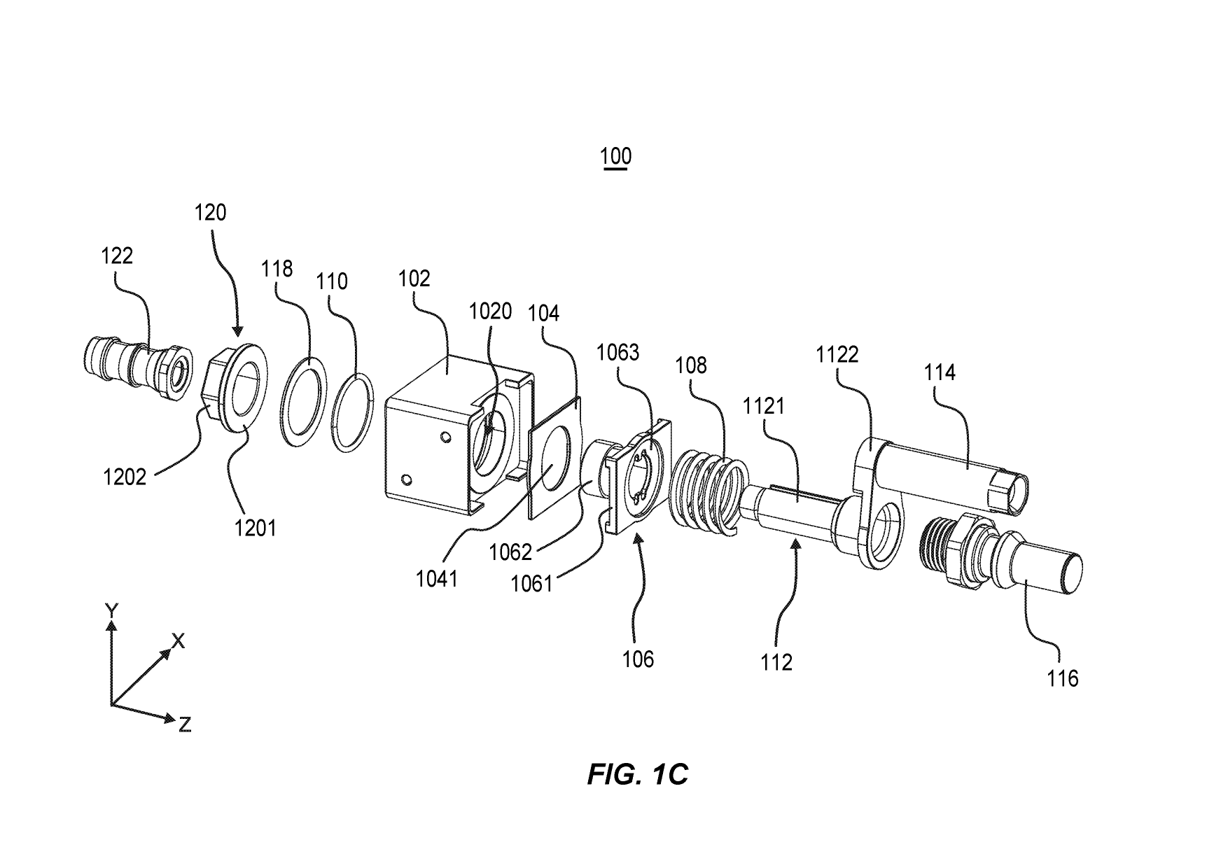

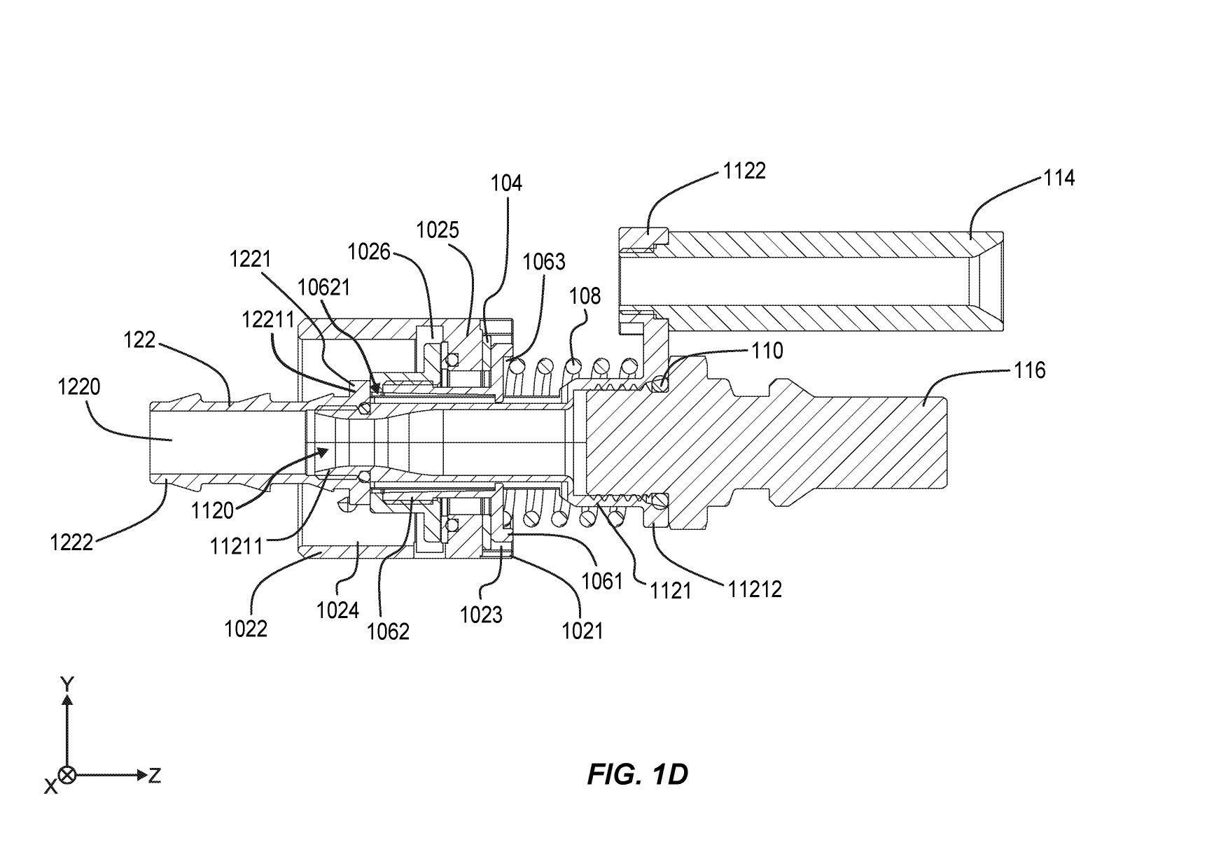

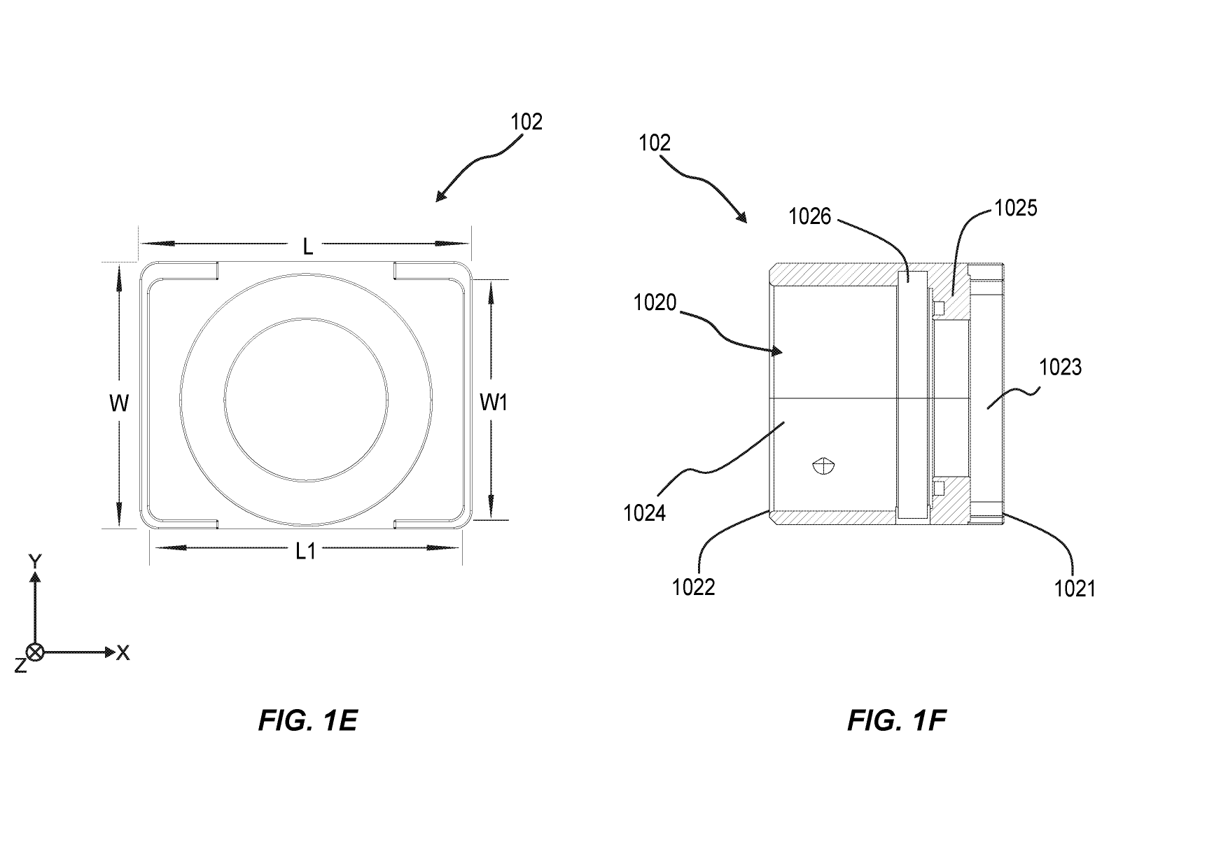

Please refer to FIGS. 1A-1E. FIGS. 1A-1B illustrate perspective views of a coupling assembly 100 according to aspects of the present disclosure. FIG. 1C illustrates an exploded perspective view of the coupling assembly 100 as shown in FIG. 1A. FIG. 1D illustrates a cross-sectional view of the coupling assembly 100 as shown in FIG. 1A. FIG. 1E illustrates a front view of a housing unit 102 of coupling assembly 100 as shown in FIG. 1A. FIG. 1F illustrates a cross-sectional view of the housing unit 102 of coupling assembly 100 as shown in FIGS. 1A.

The coupling assembly 100 includes a housing unit 102. As shown in FIG. 1F, the housing unit 102 includes a through channel 1020, a first end 1021 and a second end 1022. The housing unit 102 can have a cubic shape with a length L and a width W. As shown in FIG. 1F, the housing unit 102 has a first recessed portion 1023 at the first end 1021, which recedes towards the second end 1022. The first recessed portion 1023 includes a rectangular opening with an opening length L1 and an opening width W1. The housing has a second recessed portion 1024 at the second end 1022, which recedes towards the first end 1021. The second recessed portion 1024 includes a circular opening. A center portion 1025 is disposed between the first recessed portion 1023 and the second recessed portion 1024. The center portion 1025 has a circular opening that is smaller than the opening sizes of the first recessed portion 1023 and the second recessed portion 1024. A groove 1026 is disposed on the inner surface of the second recessed portion 1024 and is disposed adjacent to the center portion 1025. The groove 1026 includes an opening size which is equal to the opening of the first recessed portion 1023 but larger than the opening of the second recessed portion 1024.

The coupling assembly 100 further includes a slide plate 104, a slide base 106, an axial spring 108, an inlet valve 112, a guide structure 114, a quick connect fitting 116, at least one O-ring 110, a nut 120, and an outlet valve 122. The slide plate 104 is disposed in the first recessed portion 1023. The slide plate 104 includes an over-shape opening 1041 with an opening diameter in the Y-direction that is greater than an opening diameter in the X-direction. The slide plate 104 has a width equal to the opening width W1 of the first recessed portion 1023 and a length smaller than the opening length L1. Therefore, the slide plate 104 can move in the X-direction within the first recessed portion 1023.

The slide base 106 includes a flat portion 1061 and a sleeve portion 1062. The sleeve portion 1062 is inserted through the opening 1041 of the slide plate 104 and the center portion 1025 of the housing unit 102. The sleeve portion 1062 includes tapered channel 10621 that is configured with a gradually varying diameter that narrows towards the flat portion 1061. The tapered channel 10621 provides an angular float capability of approximately 2° to the inlet valve 112. The flat portion 1061 disposed on the slide plate 104 and includes a concave portion 1063 facing away from the slide plate 104. The concave portion 1063 can be used to restrict the radial movement of the axial spring 108.

The inlet valve 112 includes an inlet sleeve 1121 and guide portion 1122. The inlet sleeve 1121 has a first end 11211 that is at least partially inserted into the tapered channel 10621 of the slide base 106. The inlet sleeve 1121 has a second end 11212 that is configured to connect to the quick connect fitting 116. The inlet sleeve 1121 further includes a n inlet fluid channel 1120 that is configured for cooling fluid (not shown) to flow through. The guide portion 1122 is disposed adjacent to the second end 11212 and configured to connect to the guide structure 114. An O-ring 110 can be utilized between the quick connect fitting 116 and the inlet sleeve 1121 for maintaining liquid tight connection. In one embodiment, the quick connect fitting 116 and the inlet sleeve 1121 can have threads that fits one another for connection. In some embodiments, the quick connect fitting 116 can be connected to the inlet sleeve 1121 via alternative connection mechanisms including, but not limited to, a snap-fit connection, a twist-lock mechanism, a compression coupling, or a push-pull connector system. The second end 11212 includes a flange structure that serves as a mechanical stop for the axial spring 108, preventing the axial spring 108 from sliding out of the coupling assembly 100 during operation.

The axial spring 108 is sleeved on the inlet valve 112, and one end of the axial spring 108 is disposed in the concave portion 1063 of the slide base 106, restrict the radial movement of the axial spring 108. The other end of the axial spring 108 sits against the second end 11212 of the inlet valve 112, preventing the axial spring 108 from sliding out of the inlet value.

The nut 120 includes a flange portion 1201 and a threaded portion 1202. The nut 120 is configured to fit onto the sleeve portion 1062 of the slide base 106 for fastening. For example, the outer surface of the sleeve portion 1062 may have threads for the nut 120 to thread on. When the nut 120 is threaded onto the sleeve portion 1062, the flange portion 1201 rests in the groove 1026. The diameter of the flange portion 1201 is smaller than the opening size of the groove 1026 and greater than the opening size of the center portion 1025. Therefore, the slide base 106 can be secured in the housing unit 102 with restricted movement in the axial direction (Z-direction). Further, a washer 118 and an O-ring 110 can be utilized to establish a watertight seal between the nut 120 and the center portion 1025.

The outlet valve 122 is connected to the first end 11211 of the inlet valve 112. Specifically, the outlet valve 122 is partially fitted on the first end 11211 of the inlet valve 112. The outlet valve 122 includes an outlet fluid channel 1220 which is in fluid communication with the inlet fluid channel 1120 during operation. A first end 1221 of the outlet valve 122 is connected to the inlet valve 112 while a second end 1222 of the outlet valve 122 is configured to connect to a cooling pipe (not shown). The first end 1221 further includes a flange structure 12211 that can fit into the nut 120. The flange structure 12211 can provide mechanical stop, preventing the outlet valve 122 from being pushed into the through channel 1020 beyond the predetermined position. Furthermore, an O-ring 110 may be disposed between the outlet valve 122 and the inlet valve 112 to establish a watertight seal and provide fraction to prevent the outlet valve 122 from easily disconnecting from the inlet valve 112.

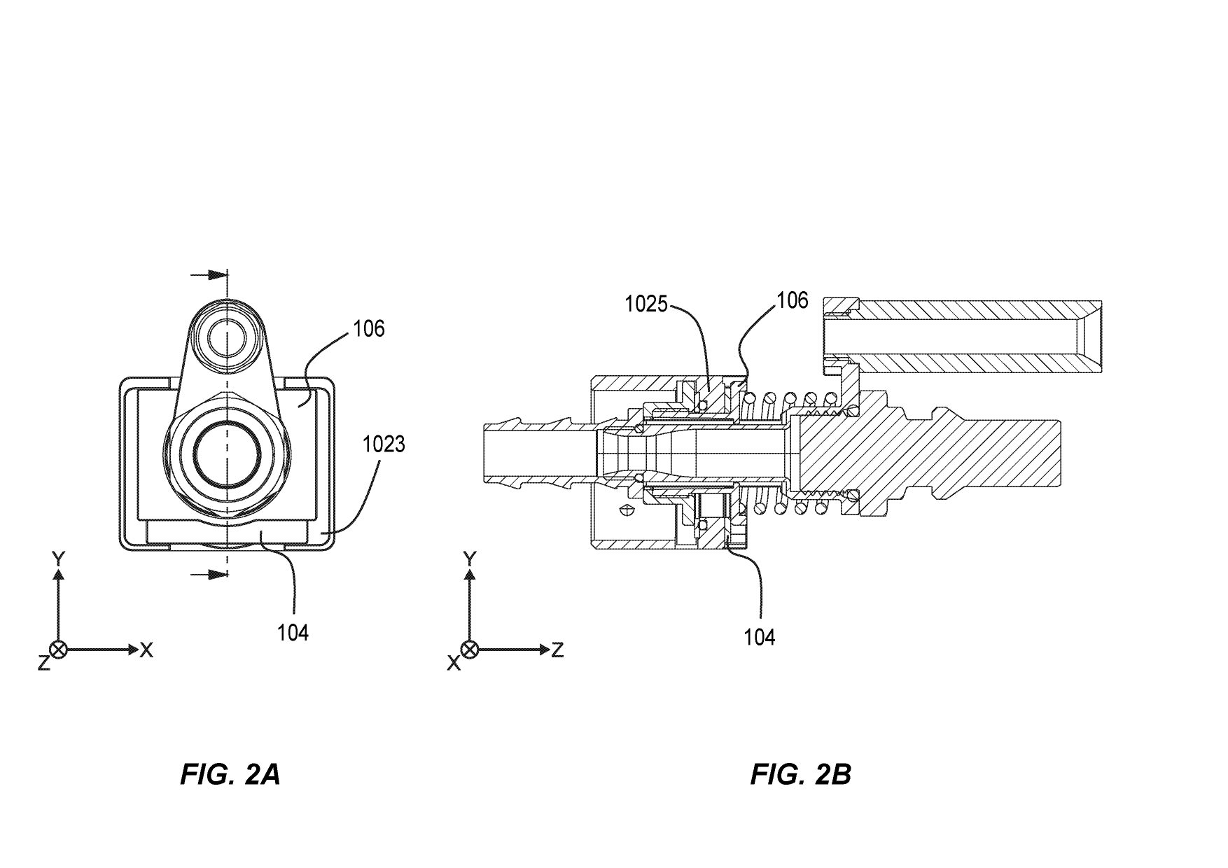

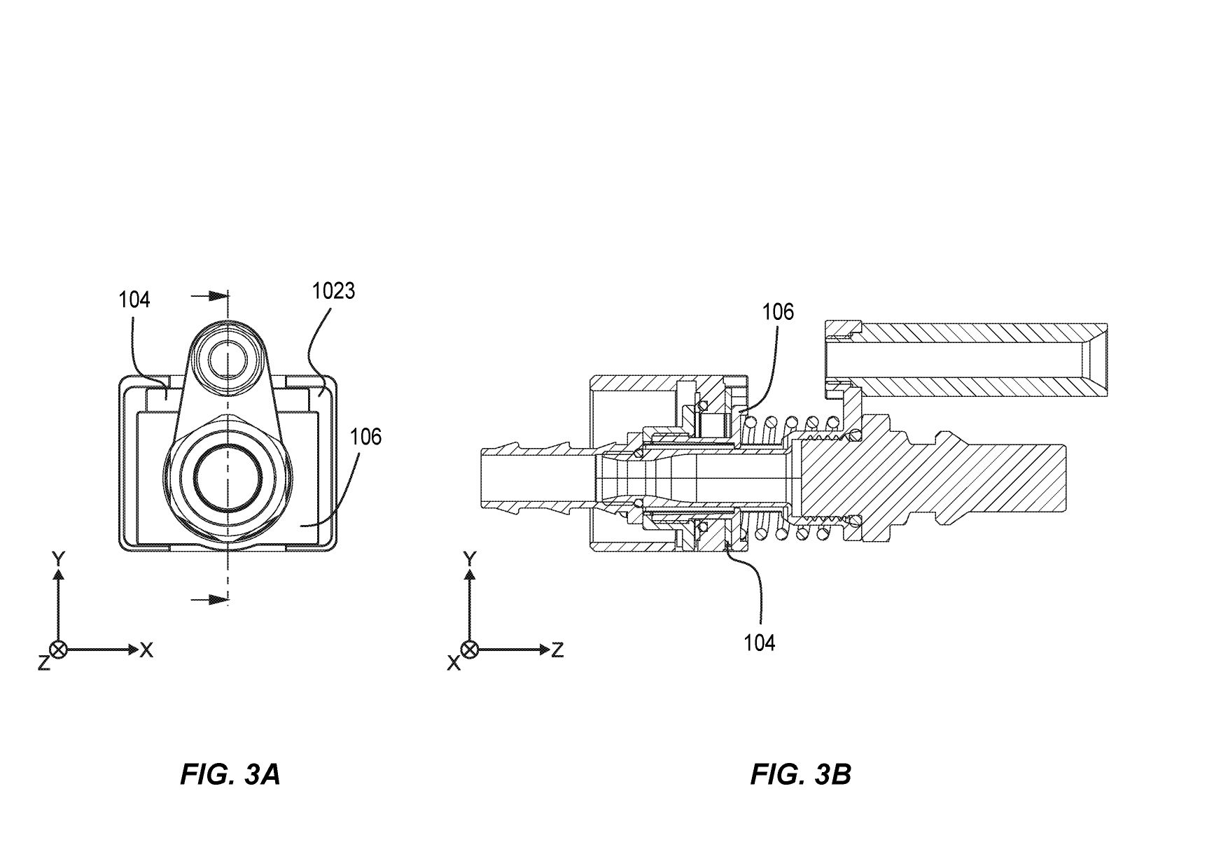

Referring to FIGS. 2A-2B, the coupling assembly 100 is illustrated in a first position along the Y-direction demonstrating radial float capability. Referring to FIGS. 3A-3B, the coupling assembly 100 is illustrated in a second position along the Y-direction demonstrating the radial float capability in the Y-direction. FIGS. 2A/3A show front views of the coupling assembly 100, whereas FIGS. 2B/3B provide cross-sectional views of the coupling assembly 100 during Y-direction movement. Because the opening 1041 of the slide plate 104 is oval-shape, the slide base 106 can move in the Y-direction. And since the slide plate 104 has a width equal to the width W1, the slide plate 104 can preserve its position within the first recessed portion 1023 along the Y-direction. Therefore, the slide base 106 is free to move the first position as shown in FIG. 2A to the second position as shown in FIG. 3A freely. Furthermore, the O-ring 110 positioned between the nut 120 and the center portion 1025 can provide continuous sealing integrity during Y-direction movement while allowing controlled friction to bring the coupling assembly 100 to stop at any position along the movement range. This friction control prevents unwanted drift while preserving the capacity to accommodate installation misalignment in the Y-direction.

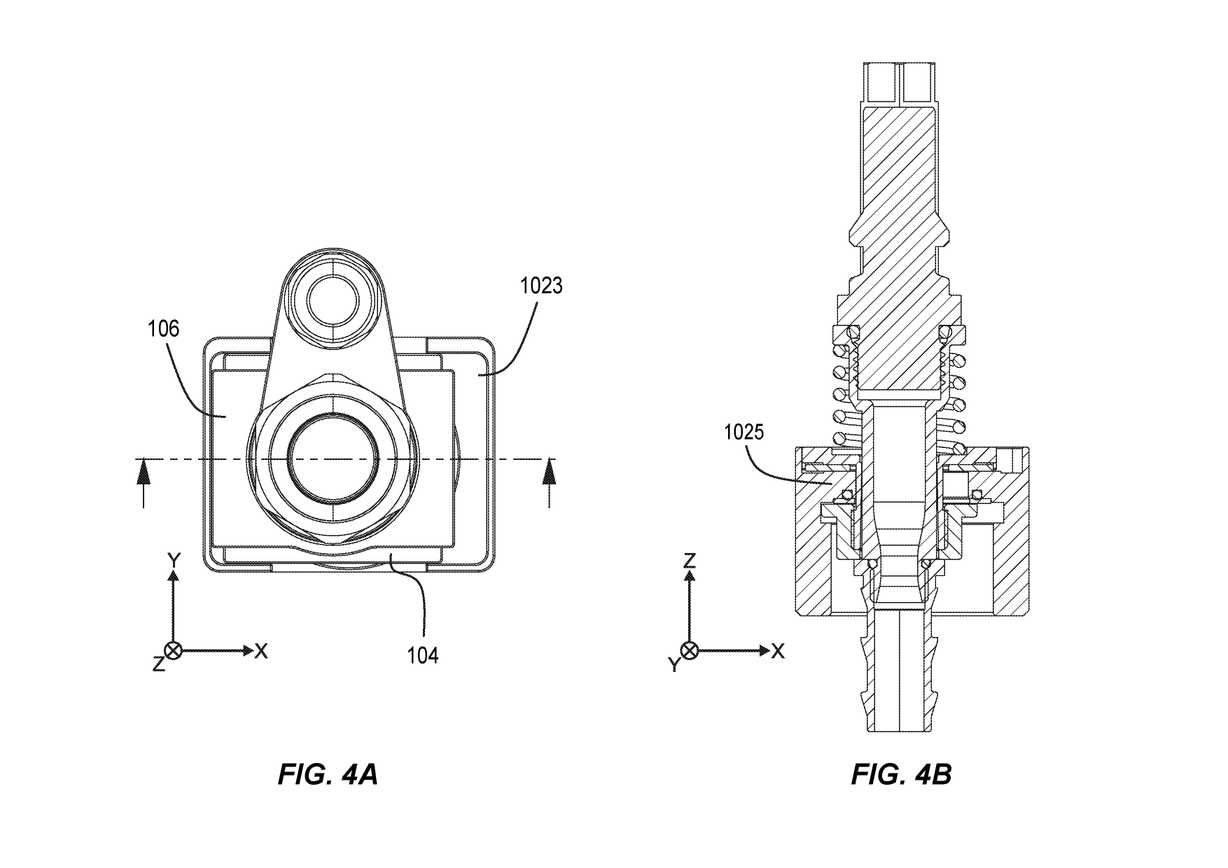

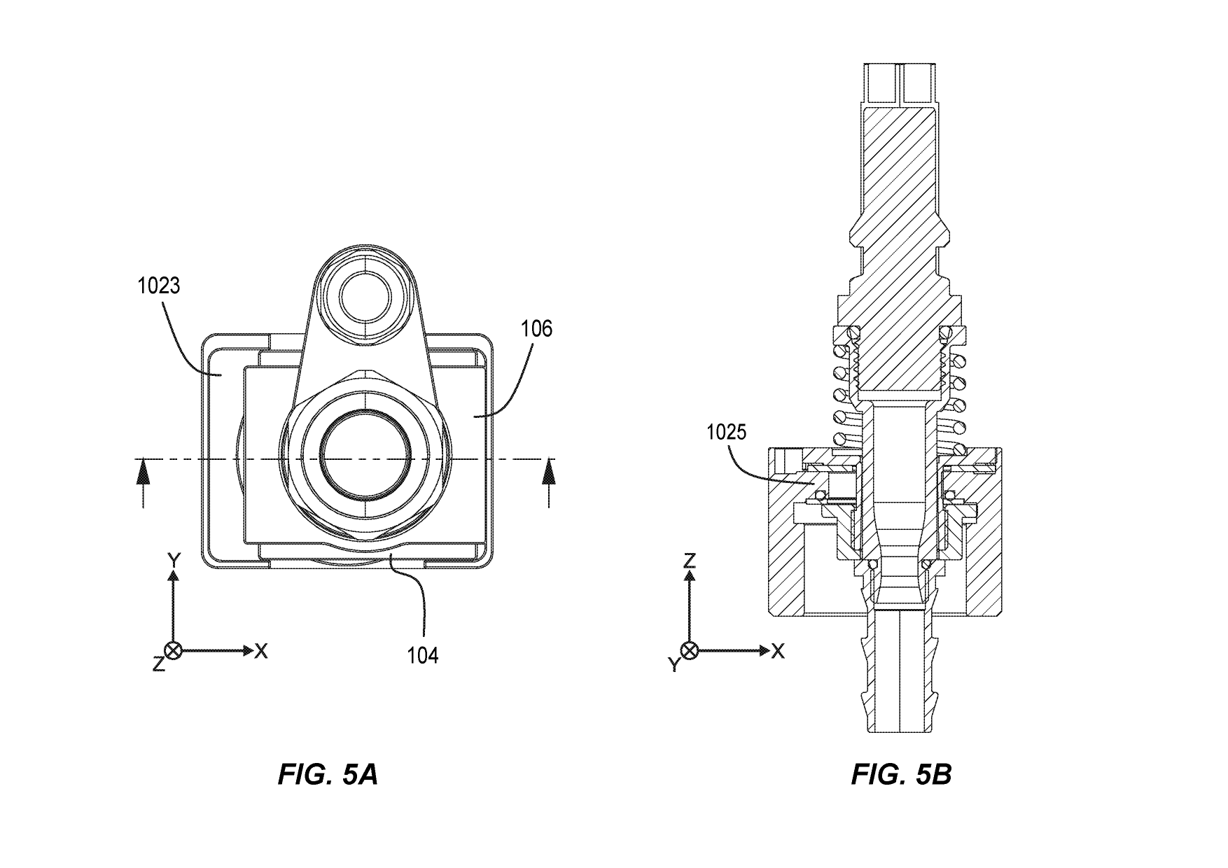

Referring to FIGS. 4A-4B, the coupling assembly 100 is illustrated in a first position along the X-direction demonstrating radial float capability. Referring to FIGS. 5A-5B, the coupling assembly 100 is illustrated in a second position along the X-direction demonstrating the radial float capability in the X-direction. FIGS. 4A/5A show front views while FIGS. 4B/5B provide cross-sectional views of the coupling assembly 100 during X-direction movement. Because the slide plate 104 has a length shorter than the opening length L1 of the first recessed portion 1023, the slide plate 104 can move in the X-direction. Also, because the slide plate 104 has a width equal to the opening width W1, the slide plate 104 can preserve its position within the first recessed portion 1023 along the Y-direction. Therefore, the slide plate 104 is free to move from the first position as shown in FIG. 4A to the second position as shown in FIG. 5A. The slide base 106 moves in tandem with the slide plate 104 during X-direction movement, preserving the structural integrity of the floating coupling assembly 100. Furthermore, the O-ring 110 positioned between the nut 120 and the center portion 1025 maintains continuous sealing integrity throughout X-direction movement while enabling controlled friction, allowing the coupling assembly 100 to stop at any position within the X-direction movement range. This friction control prevents unwanted drift while preserving the capacity to accommodate installation misalignment in the X-direction.

The coupling assembly 100 achieves comprehensive radial float capability by coordinating Y- and X-direction movements. The slide base 106 moves vertically within the first recessed portion 1023 for providing Y-direction float, while concurrently the slide plate 104 moves horizontally within the first recessed portion 1023 for providing X-direction float. This combined X-Y movement allows the coupling assembly 100 to accommodate misalignment in any radial direction within the X-Y plane, providing full radial float capability that significantly reduces mechanical stress during coupling operations.

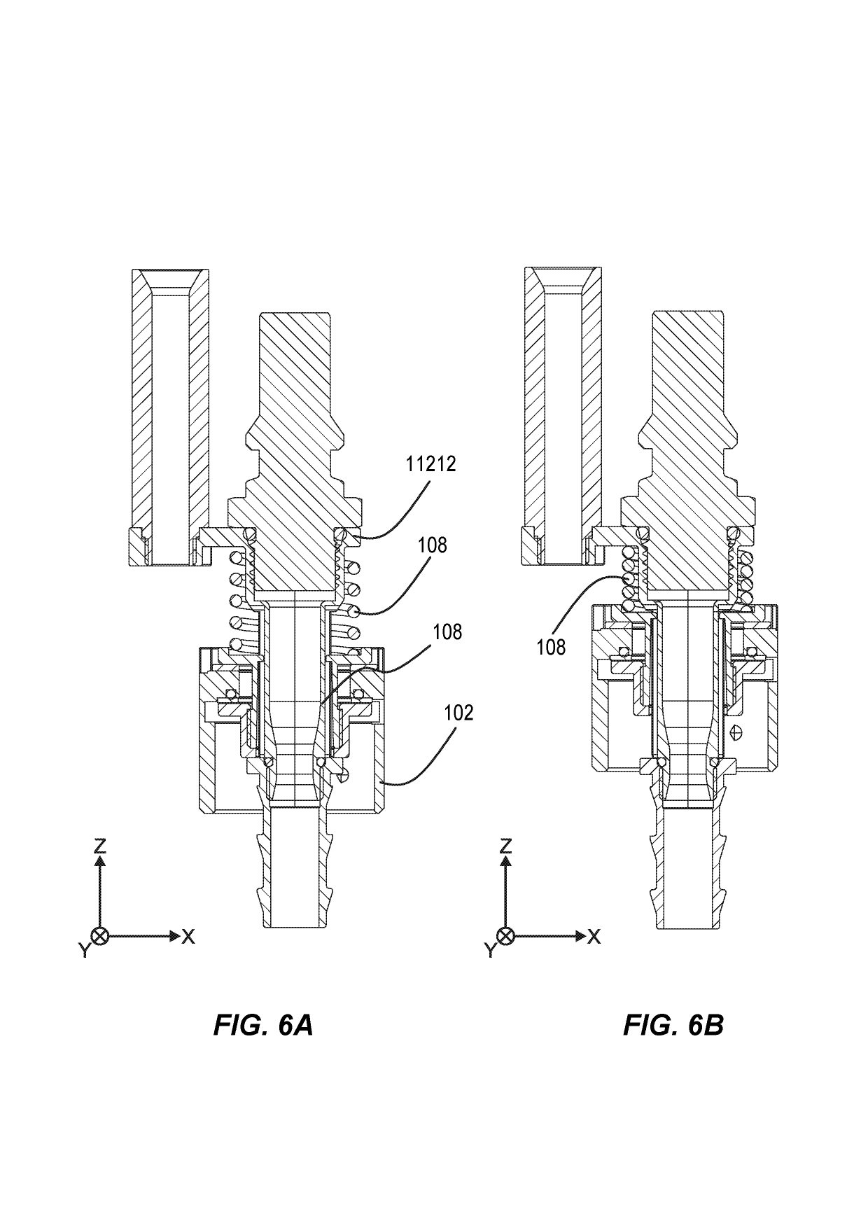

Referring to FIGS. 6A-6B, the coupling assembly 100 is illustrated demonstrating axial float capability in the Z-direction. FIG. 6A shows a cross-sectional view of the coupling assembly 100 in a first axial position while FIG. 6B shows a second axial position demonstrating the extent of axial movement. The axial spring 108 serves as a primary mechanism for Z-direction movement, compressing when the inlet valve 112 is pressed into the housing unit 102 and decompressing to restore the coupling assembly 100 to its resting position. The flange structure at the second end 11212 of the inlet valve 112 serves as a mechanical stop for the axial spring 108, retaining the spring within the coupling assembly 100 while enabling controlled axial movement. This Z-direction float capability enables the coupling assembly 100 to accommodate axial misalignment during connection operations, lowering mechanical stress and maintaining reliable fluid connections even when accurate axial alignment is not feasible during installation.

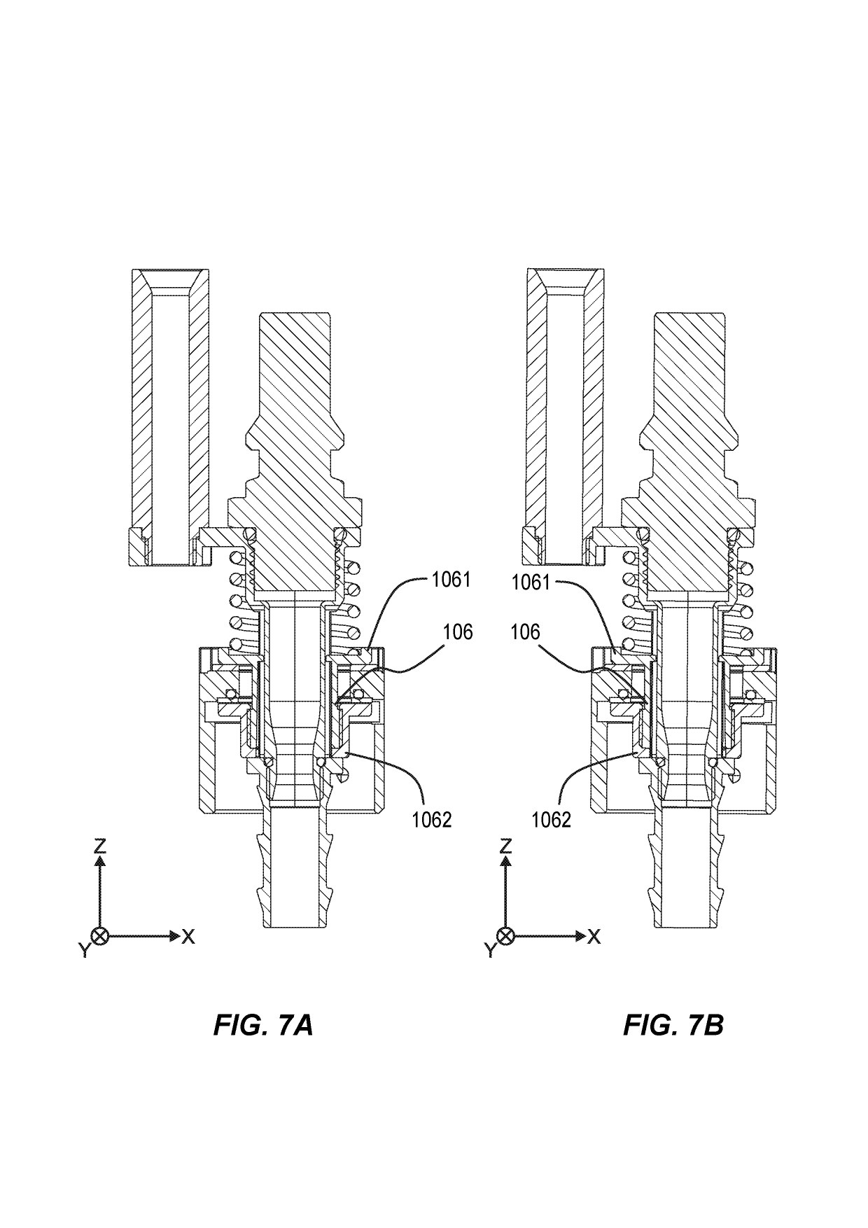

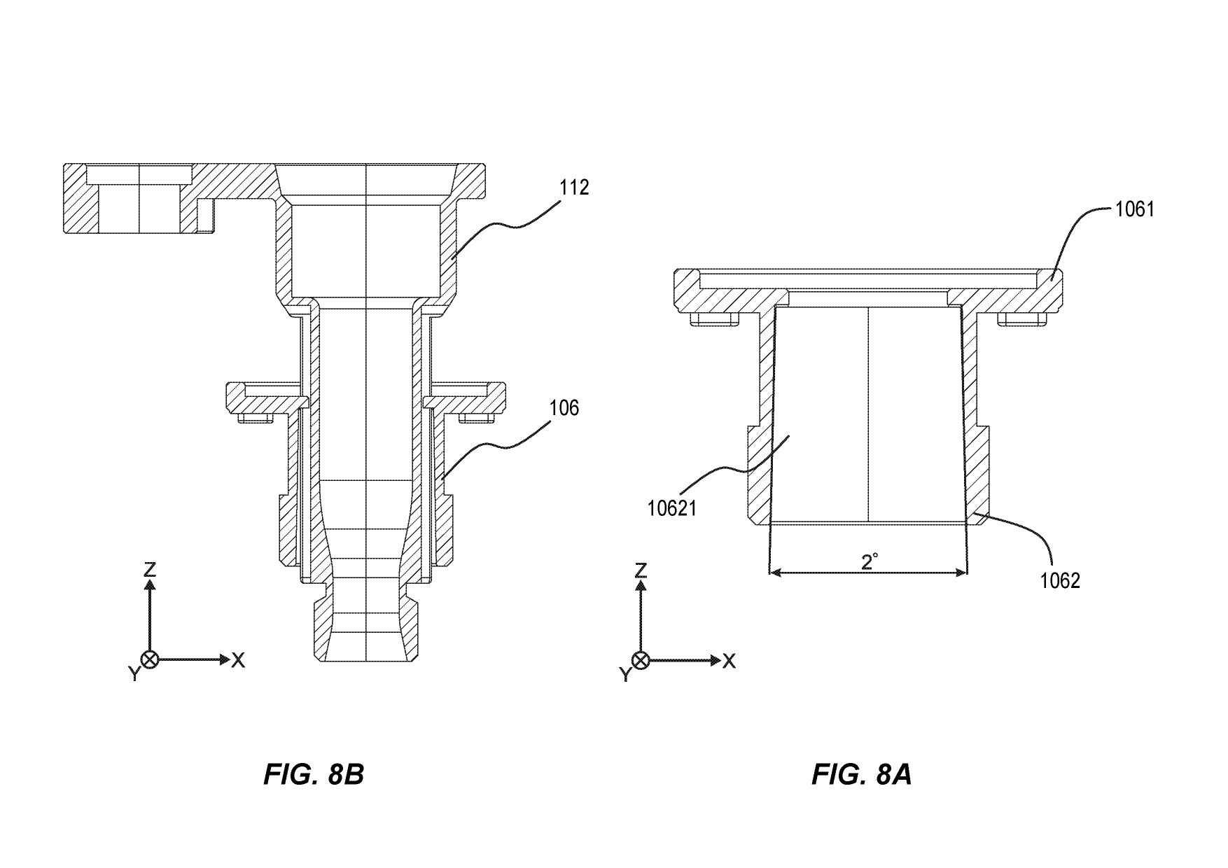

Referring to FIGS. 7A-7B and FIGS. 8A-8B, the coupling assembly 100 is illustrated demonstrating angular float capability. FIGS. 7A-7B show cross-sectional views of the coupling assembly 100 in first and second angular positions, while FIGS. 8A-8B provide enlarged cross-sectional views that further illustrate the angular movement capability. The tapered channel 10621 within the sleeve portion 1062 of the slide base 106 serves as a primary mechanism for angular movement, allowing the inlet valve 112 to pivot and move angularly relative to the slide base 106. This angular float capability of approximately 2° enables the coupling assembly 100 to preserve the capability to adjust angular misalignment during connection operations, providing flexibility that reducing mechanical stress on both the coupling assembly and connected components. The gradual change in diameter of the tapered channel 10621, which narrows towards the flat portion 1061, creates the controlled angular movement space while preserving fluid sealing integrity throughout the angular float range.

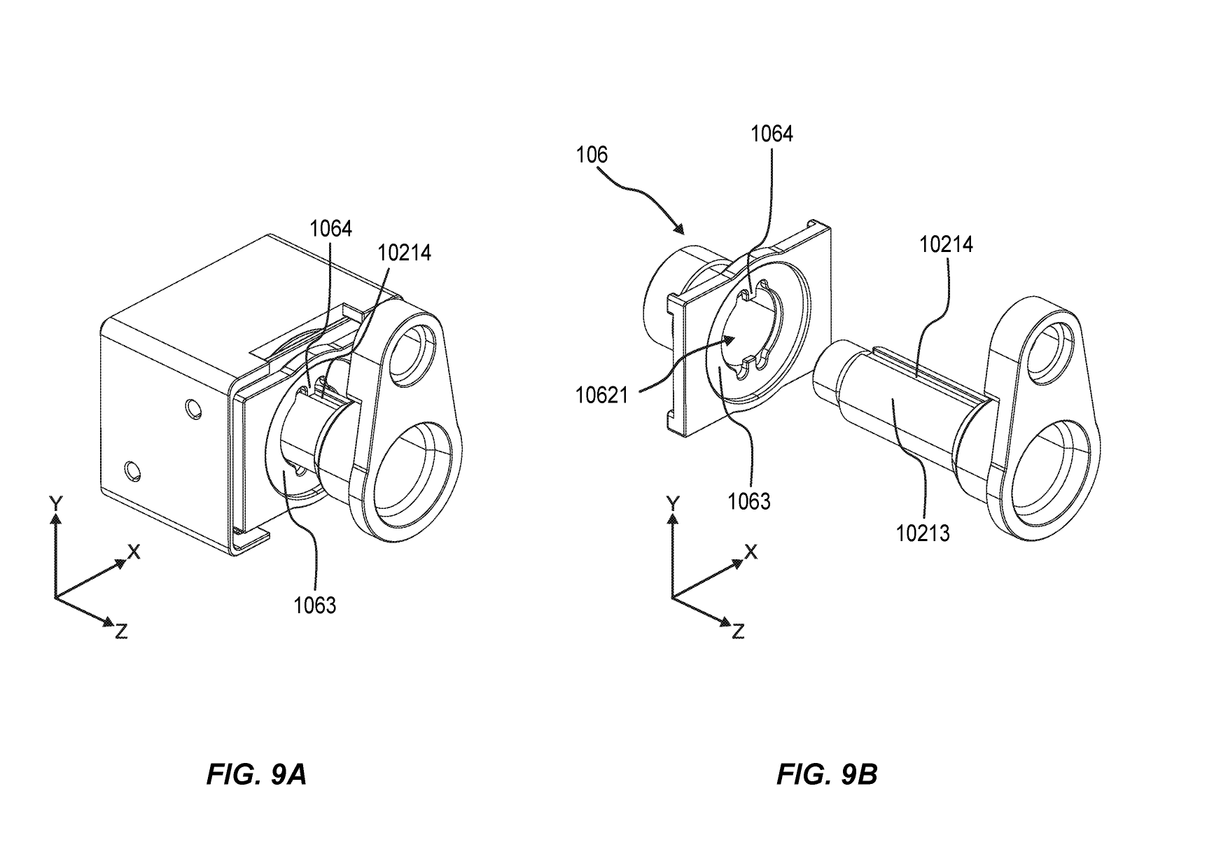

Referring to FIGS. 9A-9B, the coupling assembly 100 is shown, illustrating the rotation limiting mechanism that restricts Z-axis rotation while preserving radial and axial float capabilities. FIGS. 9A-9B show perspective views of the rotation limiting mechanism of the coupling assembly 100. In one embodiment, the slide base 106 includes a protrusion structure 1064 at the end of the tapered channel 10621 adjacent to the flanged portion 1061. In one embodiment, the inlet valve 112 includes a slot 11214 on the outer surface 11213 of the inlet sleeve 1121. The protrusion structure 1064 can engage with the corresponding slot 11214 when the inlet valve 112 is inserted through the slide base 106, preventing unwanted rotation along the Z-axis while allowing the intended radial movement in X and Y directions as well as axial movement. This rotation limiting mechanism ensures that the coupling assembly 100 maintains proper oriented during installation and prevents the components from rotating beyond their intended operational range. In some embodiments, the slide base 106 may include multiple protrusion structures arranged at angular positions around the circumference of the tapered channel 10621, enhancing rotational stability and ensuring constant alignment during blind mate coupling operations. The multiple protrusion structures can be positioned to allow for flexible orientation section while maintaining balanced engagement with the slot 11214 throughout the radial and axial movement range.

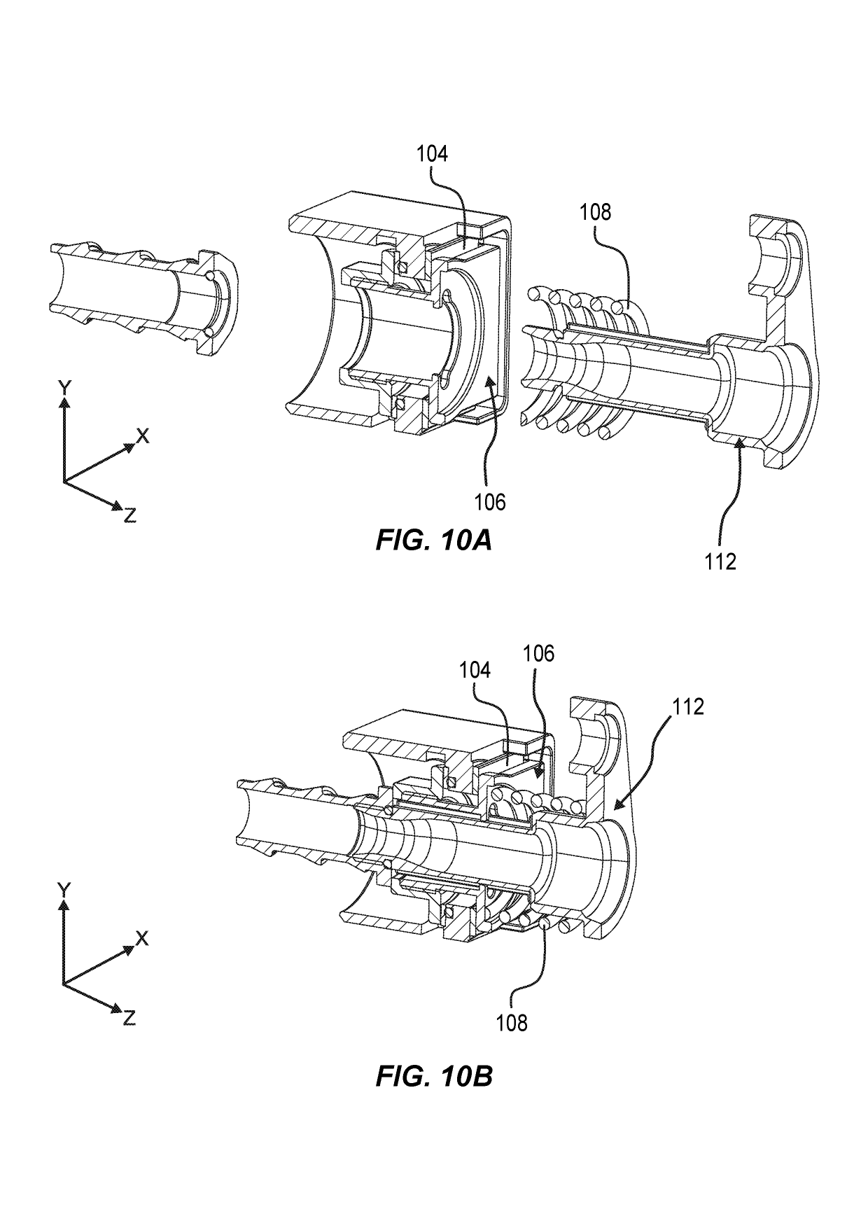

Referring to FIGS. 10A-10B, the coupling assembly 100 is shown, illustrating the friction reduction mechanism that minimizes radial friction during X-Y floating movements. FIGS. 10A-10B show enlarged cross-sectional views of the coupling assembly 100. The axial spring 108 serves as a force transmission mechanism, transmitting the spring force to the slide base 106, so minimizing X-Y floating friction during radial movement (Z-direction) operations. This force transmission mechanism mitigates stuck failure by facilitating the seamless movement of the slide base 106 and slide plate 104 within their designated movement ranges. The axial spring 108 maintains constant pressure, allowing for consistent movement, while the inlet valve 112 and associated components can move freely without binding during radial float operations. This friction reduction capability ensures the floating coupling assembly 100 operates consistently even after repeated connection and disconnection cycles, preventing mechanical binding that may compromise the multi-directional float functionality.

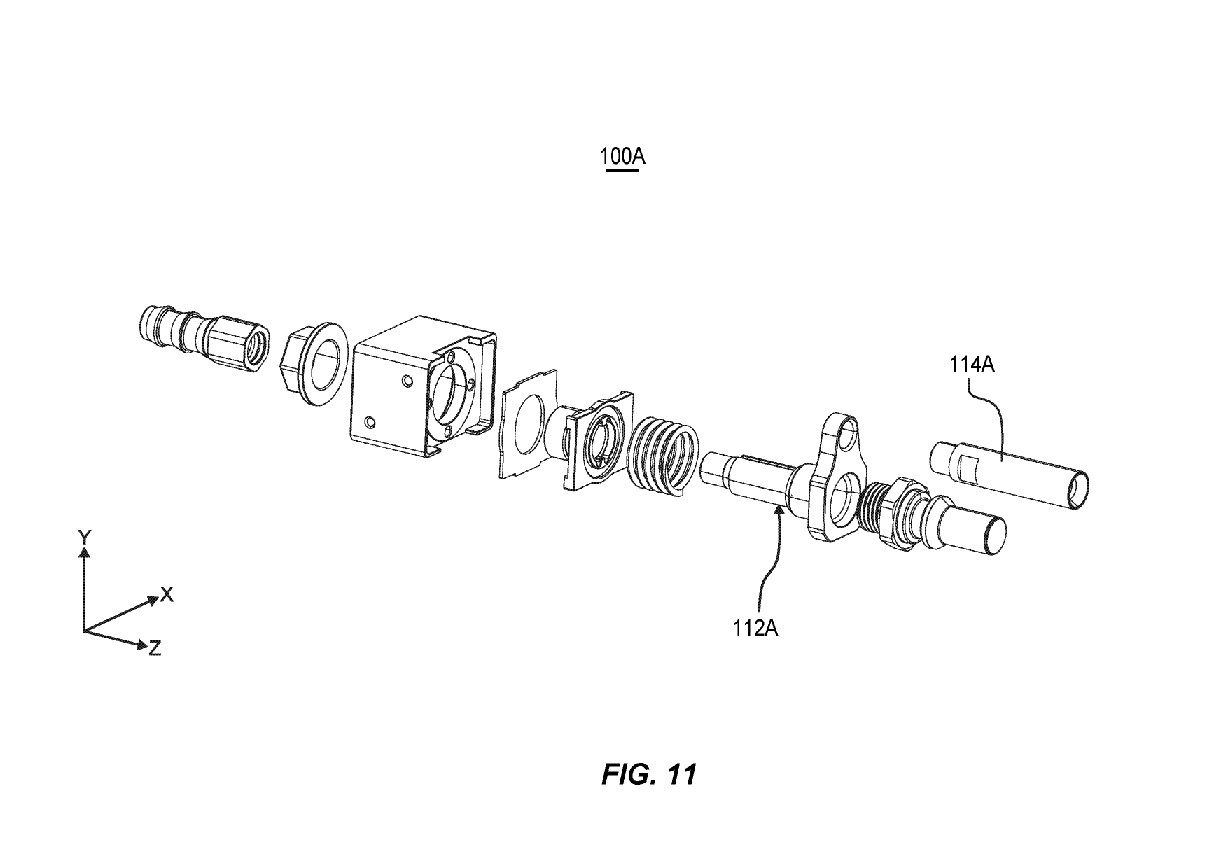

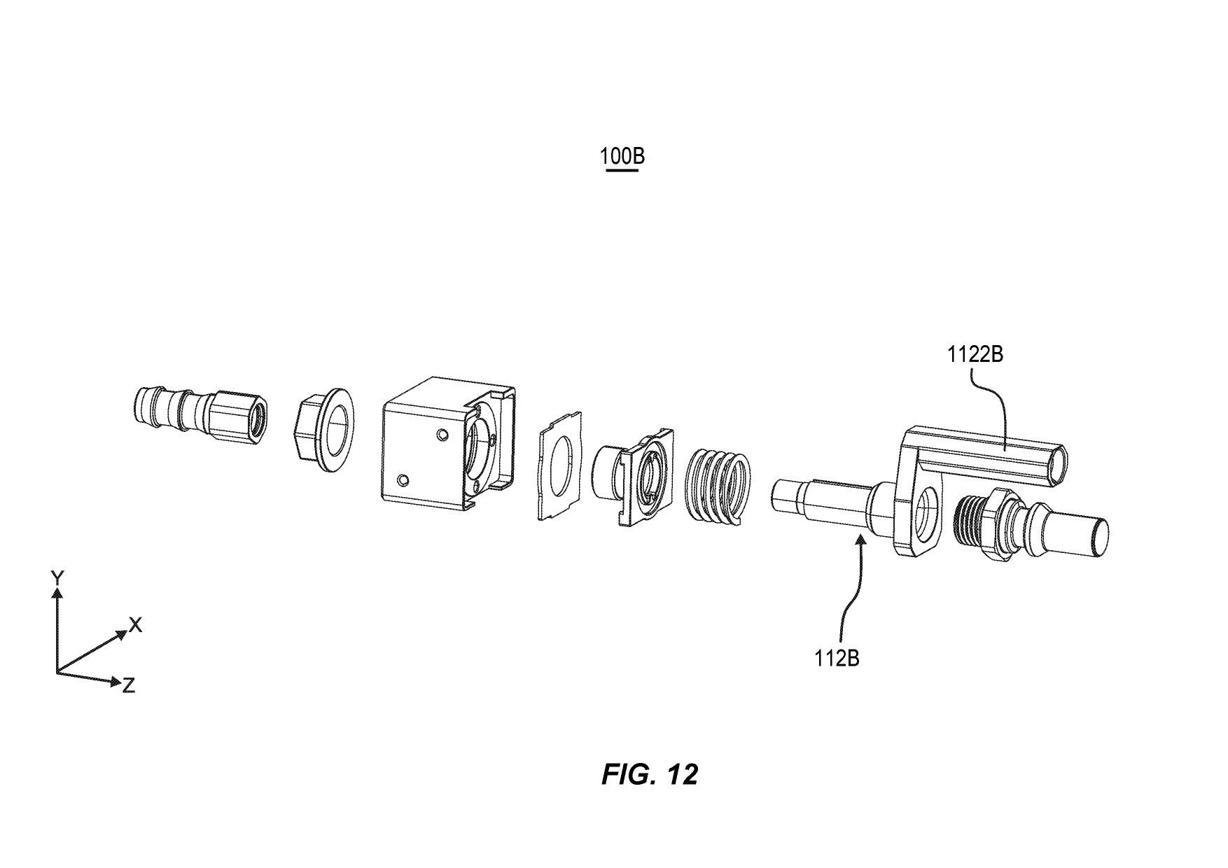

The floating coupling assembly 100, as detailed above, provides comprehensive multi-directional movement capabilities that significantly reduce mechanical stress during coupling operations. The assembly achieves radial float capability in both X and Y directions through the coordinated movement of the slide plate 104 and slide base 106, axial float capability in the Z-direction via the axial spring 108, and angular float capability of approximately 2° through the tapered channel 10621 of the slide base 106. Additionally, the rotation limiting mechanism, which includes the protrusion structure 1064 and slot 11214, prevents unwanted Z-axis rotation while preserving the intended floating movements. Building upon these fundamental floating coupling principles, FIGS. 11 and 12 illustrate two alternative embodiments of the floating coupling assembly that provide similar multi-directional movement capabilities while having different structural configurations and connection arrangements to accommodate varying application requirements.

FIG. 11 illustrates an exploded perspective view of a floating coupling assembly 100A according to aspects of the present disclosure. The coupling assembly 100A represents another embodiment as a simplified one of the coupling assembly 100, with certain components removed to reduce complexity and manufacturing costs. Specifically, the coupling assembly 100A eliminates the washer and O-ring components included in the coupling assembly 100, while preserving the core multi-directional floating capabilities, which include radial movement in X and Y directions, axial movement along the Z-direction, and angular movement of approximately 2°. The coupling assembly 100A includes a guide structure 114A detachable from the inlet valve 112A, providing enhanced serviceability and enabling straightforward replacement or reconfiguration during maintenance operations. The configuration of this detachable guide structure 114A configuration enables field servicing without requiring the entire disassembly of the coupling assembly 100A, while maintaining the alignment functionality necessary for blind mate coupling operations.

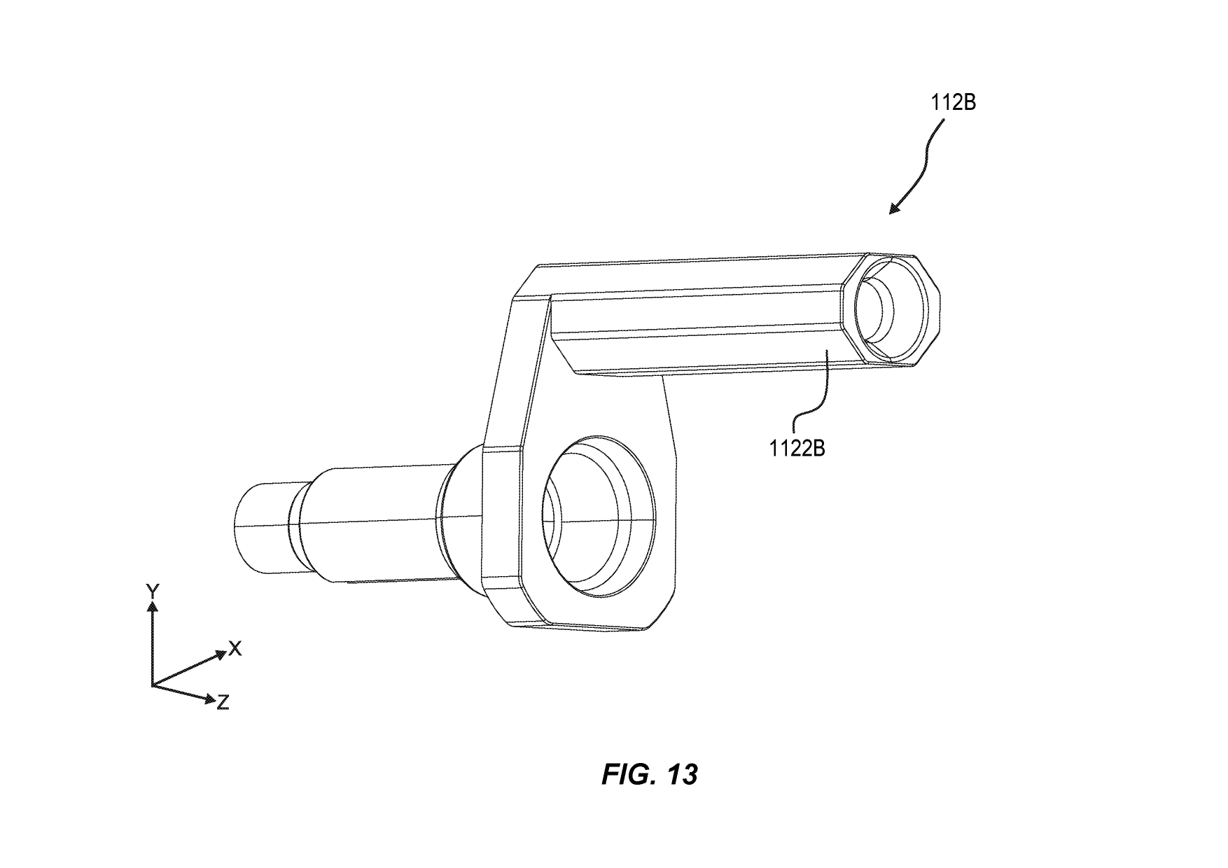

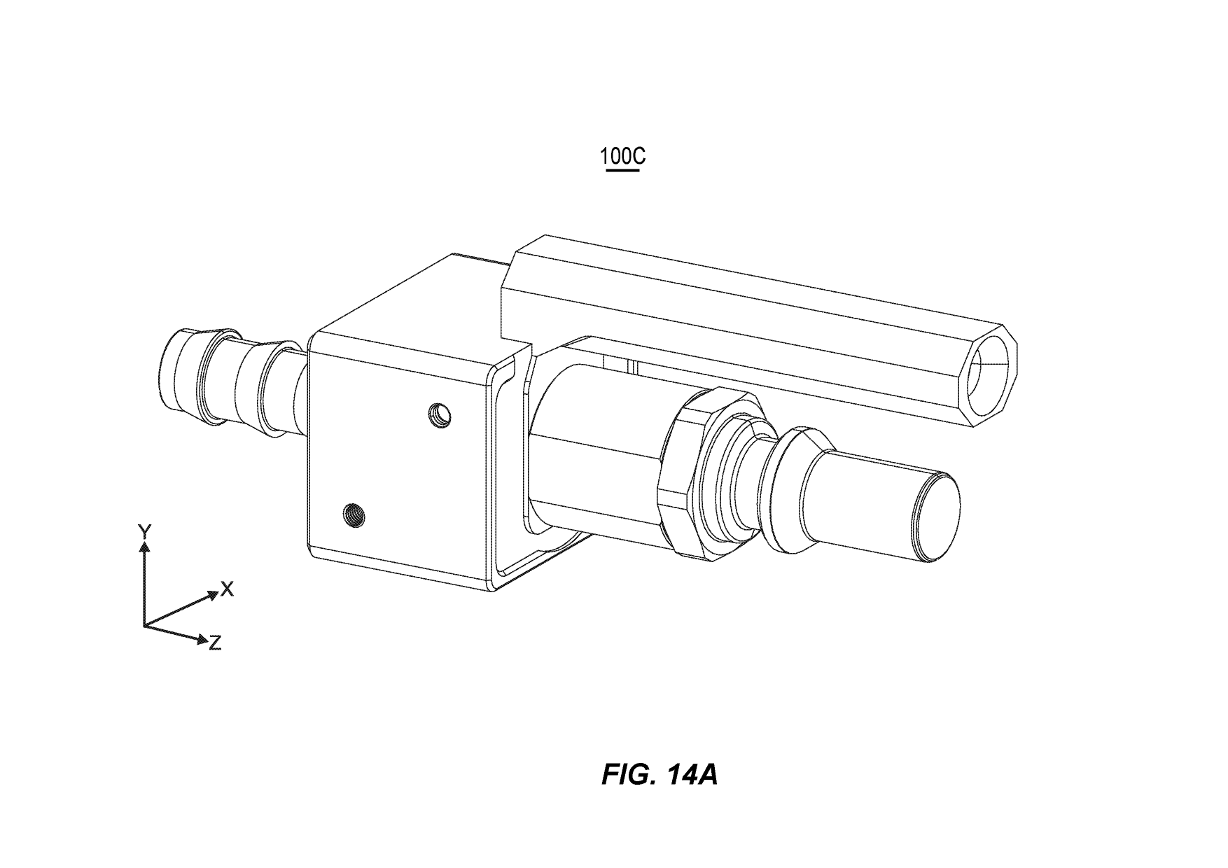

Referring to FIGS. 12-13. FIG. 12 illustrates an exploded perspective view of a coupling assembly 100B according to aspects of the present disclosure. FIG. 13 illustrates a perspective view of the inlet valve 112B of the coupling assembly 100B. The coupling assembly 100B represents another embodiment where the guide structure integrates with the inlet valve to form a single, one-piece inlet valve 112Bwith a guide portion 1122B. This one-piece design of the inlet valve 112B eliminates the need for additional fastening mechanisms between the guide structure and inlet valve, reducing manufacturing complexity and potential failure points while maintaining the essential alignment functionality for blind mate coupling operations. The integrated inlet valve 112B enhances structural integrity and simplifies assembly procedures, as the guide structure is integrally formed with the inlet sleeve 1121 during manufacturing.

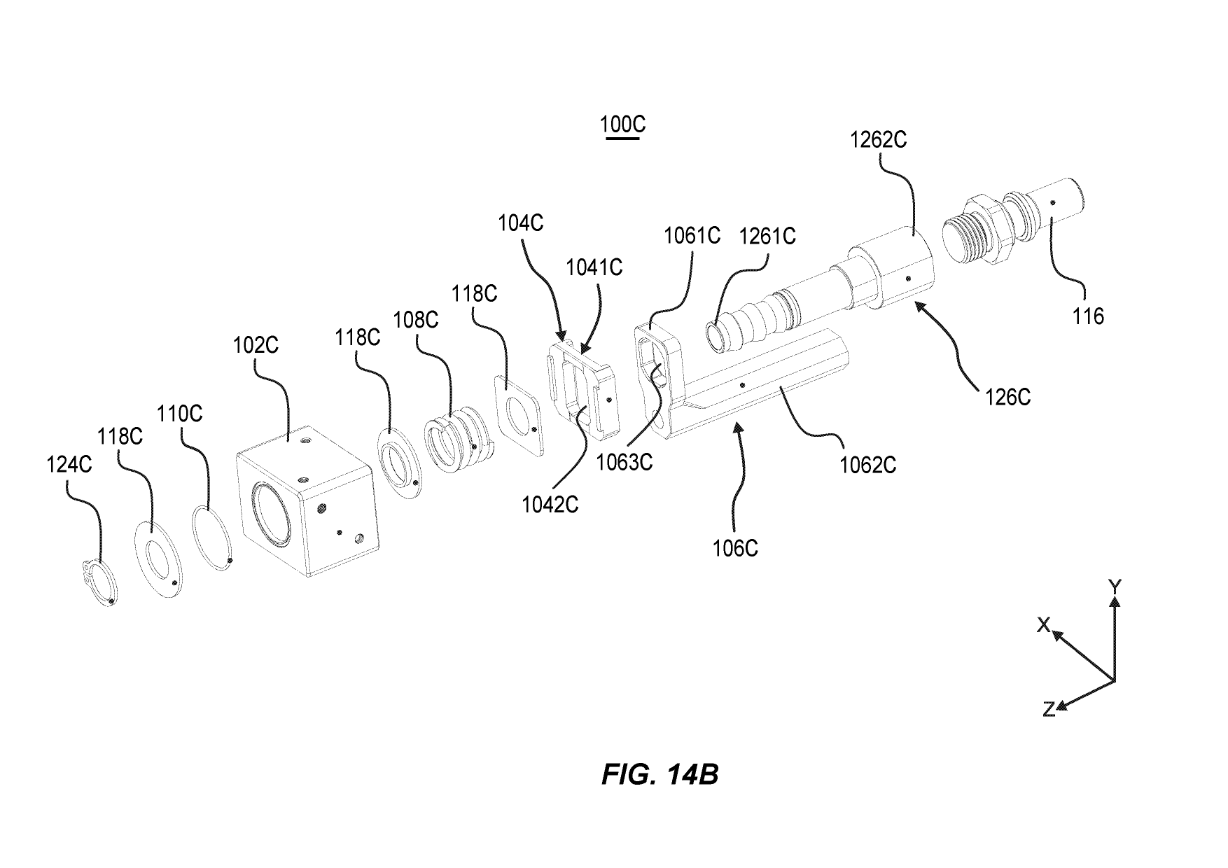

Please refer to FIGS. 14A-14B. FIG. 14A illustrates a perspective view of a floating coupling assembly 100C according to aspects of the present disclosure. FIG. 14B illustrates an exploded perspective view of the floating coupling assembly 100C shown in FIG. 14A. The coupling assembly 100C represents another embodiment of another simplified coupling assembly that maintains the essential multi-directional floating capabilities while reducing overall component count and manufacturing complexity when compared to the previously described assemblies 100, 100A, and 100B. This simplified configuration eliminates certain components while preserving the core floating connector functionality, which includes radial movement in X and Y directions and axial movement along the Z-direction.

The coupling assembly 100C includes the fundamental components necessary for the floating coupling operation, arranged in a streamlined configuration. As shown in FIG. 14B, the coupling assembly 100C includes a housing unit 102C, slide plate 104C, slide base 106C, axial spring 108C, O-ring 110C, quick connect fitting 116, multiple washers 118C that provide structural support and spacing between components, a clamp 124C that secures the components together, and a combined valve 126C that integrates fluid connection functionality into a single component.

The slide plate 104C and slide base 106C work together to provide the multi-directional radial float capability required for the coupling assembly 100C functionality. The slide plate 104Cis disposed within the housing unit 102C and is configured to move in the X-direction relative to the housing unit 102C. The slide plate 104Cincludes a recessed portion 1041C facing the slide base 106C. This recessed portion 1041C is configured to restrict Y-direction movement of the slide base 106C. The slide plate 104C includes an opening 1042C that allows the combined valve 126C to pass through.

The coupling assembly 100C combines the guide structure with the slide base into one single piece, forming the slide base 106C. The slide base 106Cincludes a slide portion 1061C and a guide portion 1062C. The slide portion 1061Cfunctions similar to the slide base 106/106A/106Bof the coupling assembly 100/100A/100Bto provide Y-direction movement. The slide portion 1061C is disposed within the recessed portion 1041C of the slide plate 104C, thereby restricting its X-direction movement. The guide portion 1062C functions similar to the guide structure 114/114Aor the guide portion 1122B of the inlet valve 112B. An opening 1063Cof the slide base 106C is disposed on the slide portion 1061C, allowing the combined valve 126C to pass through. The coordinated movement between the slide plate 104C and slide base 106C enables the coupling assembly 100C to accommodate radial misalignment in any direction within the X-Y plane. When external forces are applied during coupling operations, the slide plate 104Ccan move in the X-direction while the slide base 106C simultaneously moves in the Y-direction, resulting in a combined radial float capability that can reduce mechanical stress on both the coupling assembly 100C and the connected components.

Compared to axial spring 108/108A/108B, the axial spring 108C is disposed within the housing unit 102C. The valve 126C passes through the axial spring 108C. Two washers 118Csandwich the axial spring 108C. stabilizing spring end conditions, preventing damages to the housing unit 102C and the slide plate 104C, and ensuring uniform force distribution during compression cycles.

The inlet valve 112/112A/112Band outlet valve 122/122A/122B are separate components that are connected within or near the slide base to establish a fluid flow path. In contrast, the valve 126C integrates both the inlet and outlet fluid connection functions into one single piece. The combined valve 126C includes a fluid channel (not shown) extending from a first end 1261C to a second end 1262C, allowing cooling fluid to flow through the combined valve 126C during operation. This integration eliminates the internal valve-to-valve connection interface, reducing the number of potential leak spots and simplifying the overall assembly process. The combined valve 126C passes through the openings 1042C, 1063C, the axial spring 108C, various washers 118C and the housing unit 102C. A clamp 124C, along with a washer 118C and an O-ring 110Ccan be utilized to prevent the combined valve 126C at a first end 1261C from sliding out of the housing unit 102C. A quick connect fitting 116 can be connected to the second end 1262C of the combined valve 126C. This simplified design reduces manufacturing costs, shortens assembly duration, and improves reliability by minimizing the number of sealing interfaces, while preserving the essential floating coupling capabilities including radial X-Y movement and axial Z-direction movement.

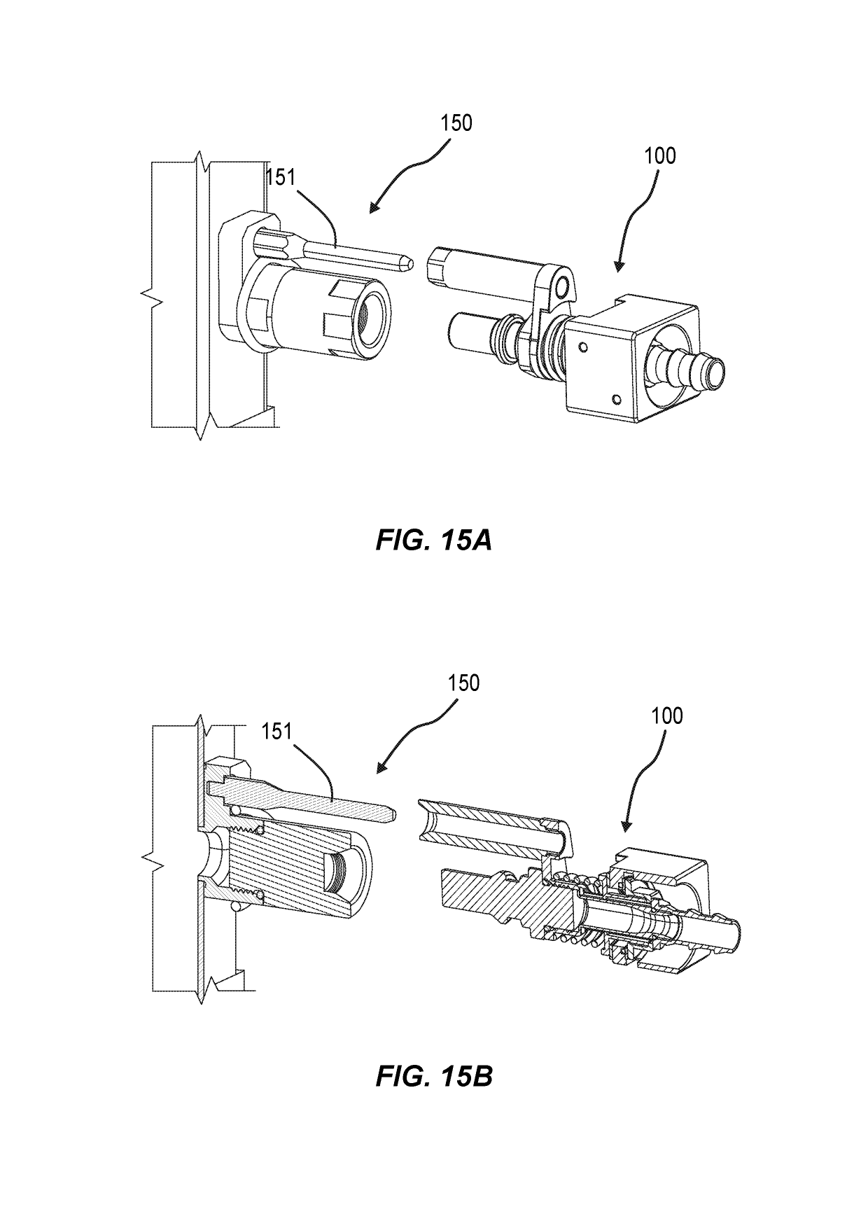

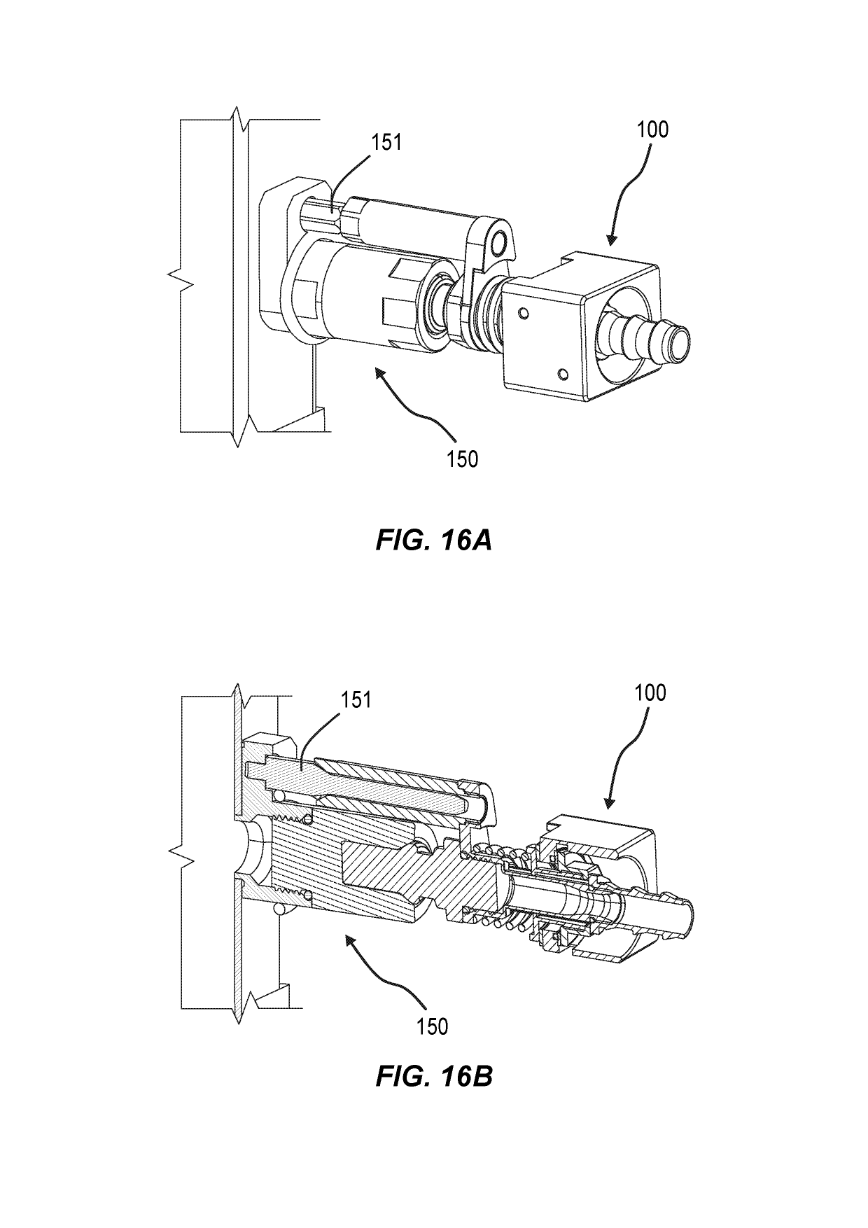

Please refer to FIGS. 15A-16B. FIGS. 15A-15B illustrate the coupling assembly 100 in a detached position during operation. FIGS. 16A-16B illustrate the coupling assembly 100 in an attached position during operation. The coupling assembly 100 can be used to connect to a mating connector 150 of a liquid cooling system component, such as a manifold, cold plate, radiator, pump, reservoir, or other fluid distribution or heat exchange device used in electronic cooling applications. The mating connector 150 is typically mounted to or integrated into the cooling system component and includes a guide pin 151 that extends from the mating connector surface to facilitate alignment during the blind mate coupling operation.

During the coupling operation, the guide structure 114 of the coupling assembly 100 engages with the corresponding guide pin 151 extending from the mating connector 150. The guide structure 114 receives and aligns with the guide pin 151 to direct the coupling assembly 100 toward the proper engagement position, thus facilitating the blind mate connection process despite initial misalignment between components. As the coupling advances, the guide structure 114 maintains alignment with the guide pin 151 while the inlet valve 112 and outlet valve 122 establish their fluid connections with the mating connector 150 of the cooling system component. The multi-directional floating capabilities of the coupling assembly 100, including radial movement in the X-Y plane, axial movement in the Z-direction, and angular float, work together to accommodate misalignment during the coupling operation, reducing mechanical stress and enabling reliable blind mate connections without requiring precise pre-alignment.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A coupling assembly for a blind mate fluid coupling, comprising:
a housing unit having a first end and a second end, the housing unit includes a through channel extending in an axial direction from the first end to the second end, the housing unit having a first recessed portion at the first end;
a slide plate disposed in the first recessed portion and movable in a first radial direction relative to the housing unit, the first radial direction being perpendicular to the axial direction, the slide plate includes an opening;
a slide base having a flat portion and a sleeve portion, the sleeve portion extending through the opening of the slide plate, the slide base being movable in a second radial direction relative to the slide plate, the second radial direction being perpendicular to both the axial direction and the first radial direction, wherein the sleeve portion includes a tapered channel configured with a gradually narrowing diameter towards the flat portion; and
an inlet valve at least partially disposed in the tapered channel of the slide base, the inlet valve being movable in the axial direction and angularly pivotable within the tapered channel.

2. The coupling assembly of claim 1, wherein the opening of the slide plate has an oval shape with a first opening diameter along the second radial direction greater than a second opening diameter along the first radial direction, allowing the slide base to move in the second radial direction.

3. The coupling assembly of claim 1, wherein the slide plate has a width equal to an opening width of the first recessed portion and a length shorter than an opening length of the first recessed portion, allowing the slide plate to move in the first radial direction.

4. The coupling assembly of claim 1, further comprising:
an outlet valve connected to a first end of the inlet valve, the outlet valve being in fluid communication with an inlet fluid channel of the inlet valve during operation, wherein the outlet valve includes a flange structure facing the inlet valve.

5. The coupling assembly of claim 4, further comprising:
a spring sleeved on the inlet valve, wherein one end of the spring is disposed in a concave portion of the flat portion of the slide base and the other end of the spring is disposed against a second end of the inlet valve, the spring being configured to provide axial movement in the axial direction and being retained between the slide base and the inlet valve.

6. The coupling assembly of claim 5, wherein the flat portion of the slide base includes the concave portion configured to restrict radial movement of the spring.

7. The coupling assembly of claim 1, further comprising:
a nut configured to secure on the sleeve portion of the slide base, the nut including a flange portion disposed in a groove of the housing unit, wherein a diameter of the flange portion is smaller than an opening size of the groove of the housing unit and greater than an opening size of a center portion of the housing unit.

8. The coupling assembly of claim 7, further comprising:
at least one O-ring disposed between the nut and the housing unit.

9. The coupling assembly of claim 5, further comprising:
a guide structure connected to the inlet valve at the second end and configured to engage with a guide pin extending from a mating connector for blind mate coupling.

10. The coupling assembly of claim 9, wherein the guide structure is detachable from the inlet valve.

11. The coupling assembly of claim 9, wherein the guide structure is integrally formed with the inlet valve.

12. The coupling assembly of claim 1, further comprising:
at least one protrusion structure disposed on the slide base and a slot disposed on an outer surface of the inlet valve, wherein the at least one protrusion structure engages with the slot to prevent rotation around the axial direction.

13. The coupling assembly of claim 1, wherein the tapered channel provides angular movement of 2° or less than 2° to the inlet valve.

14. The coupling assembly of claim 4, wherein the second end of the inlet valve includes a flange structure configured to retain the spring on the inlet valve.

15. The coupling assembly of claim 1, further comprising:
a quick connect fitting connected to the second end of the inlet valve.

16. The coupling assembly of claim 11, wherein the slide base includes multiple protrusion structures disposed at angular positions around a circumference of the tapered channel.

17. A coupling assembly for a blind mate fluid coupling, comprising:
a housing unit;
a slide plate disposed within the housing unit and configured to move in a first radial direction, the slide plate including a recessed portion and an opening;
a slide base including a slide portion and a guide portion, the slide portion disposed in the recessed portion of the slide plate and configured to move in a second radial direction perpendicular to the first radial direction, wherein the guide portion is configured to engage with a guide pin of a mating connector; and
a valve having a first end and a second end, the valve extending through the opening of the slide plate and the slide base, wherein the valve includes a fluid channel extending from the first end to the second end.

18. The coupling assembly of claim 17, wherein the recessed portion of the slide plate is configured to restrict movement of the slide base in the first radial direction.

19. The coupling assembly of claim 17, further comprising:
a spring disposed inside the housing unit, wherein the valve passes through the spring.

20. The coupling assembly of claim 19, further comprising:
a clamp configured to secure the valve at the first end from sliding out of the housing unit; and
a quick connect fitting connected to the second end of the valve.
